(19) United States
(12) Patent Application Publication
(10) Pub. No.: US 2016/0360630 A1
(43) Pub. Date: Dec. 8, 2016

(54) CASING AND CAP ASSEMBLY FOR ELECTRONIC DEVICES

(71) Applicant: SONY MOBILE COMMUNICATIONS INC., Tokyo (JP)

(72) Inventor: Tomohito ODA, Tokyo (JP)

(73) Assignee: SONY MOBILE COMMUNICATIONS INC., Tokyo (JP)

(21) Appl. No.: 15/171,419

(22) Filed: Jun. 2, 2016

Related U.S. Application Data
(60) Provisional application No. 62/170,281, filed on Jun. 3, 2015.

(51) Int. Cl. H05K 5/02; A45F 5/00; H05K 5/00; G06F 1/16; G06F 1/18; A45C 11/00; A45C 13/10

(52) U.S. Cl. CPC H05K 5/0239; A45C 11/00; A45F 5/00; A45C 13/10; G06F 1/1656; G06F 1/181; H05K 5/0086; A45C 2011/001; A45C 2011/002; A45C 2011/003

(57) ABSTRACT

A casing and cap assembly comprises a cap and a casing to receive the cap. The cap includes at least one member, a leg with a first end attached to the at least one member, and a stop attached to a second end of the leg. The stop includes a first side and a second side directly adjacent to and narrower than the first side. The casing includes an opening to provide access to the electronic receptacle and to receive the at least one member; and a latching hole connected to the opening, to receive and guide the stop when the stop is in a first orientation, and configured to slide and block the stop when the stop is in a second orientation. In the first orientation, the first side of the stop is facing upward while in the second orientation, the second side of the stop is facing upward.

### CROSS-REFERENCE TO RELATED APPLICATIONS

This application is based on, and claims the benefit of priority to, provisional application No. 62/170,281, filed Jun. 3, 2015, the entire contents of which are incorporated herein by reference.

### BACKGROUND

Field of the Disclosure

The present disclosure relates to casing and cap assemblies for electronic devices.

Description of the Related Art

Electronic devices, e.g. personal computers, tablets, phones, media players, cameras, or the like, are often equipped with a casing having electronic receptacles, e.g. memory card slots, USB inputs, electric inputs, or the like, that may require protection against external elements, e.g. water, dust, dirt, or the like.

These electronic receptacles are usually lodged inside openings of a surface of the casing, wherein the openings are configured to receive caps to ensure protection against the external elements.

These casing and cap assemblies usually rely on latching mechanisms to avoid unwanted separation between the casing of the electronic device and the cap that may result in losing the cap and leaving the electronic receptacle unprotected.

However, these conventional casing and cap assemblies rely on latching mechanisms that may be cumbersome, difficult and time consuming to use.

Thus, a casing and cap assembly having latching mechanisms solving the above-mentioned limitation of usability is desired.

### SUMMARY

Accordingly, the object of the present disclosure is to provide a casing and cap assembly for electronic devices which overcomes the above-mentioned limitation.

The casing and cap assembly of the present disclosure addresses the limitation of ease of use by providing a latching mechanism configured to attach, detach, and reattach the cap to the casing via simple manipulations of the cap such as inserting, rotating or sliding.

In one non-limiting illustrative example, a casing and cap assembly comprising a casing and a cap is presented. The cap includes a first member to provide protection against external elements; a second member stacked on the first member; a third member stacked on the second member and configured to act as a seal for an electronic receptacle; a leg with a first end attached to the second member; and a stop attached to a second end of the leg, the stop having a first side, and a second side directly adjacent to the first side and narrower than the first side. The casing includes an opening to provide access to the electronic receptacle and to receive the first member, and a latching hole connected to the opening, configured to receive and guide the stop when the stop is in a first orientation, and configured to slide and block the stop when the stop is in a second orientation, wherein in the first orientation the first side of the stop is facing upward, and in the second orientation the second side of the stop is facing upward.

In another one non-limiting illustrative example, a casing and cap assembly comprising a casing and a cap is presented. The cap includes at least one member; a leg with an first end attached to the at least one member; and a stop attached to a second end of the leg, the stop having a first side, and a second side directly adjacent to the first side and narrower than the first side. The casing includes an opening to provide access to an electronic receptacle and to receive the at least one member, and a latching hole connected to the opening, configured to receive and guide the stop when the stop is in a first orientation, and configured to slide and block the stop when the stop is in a second orientation, wherein the first orientation the first side of the stop is facing upward, and in the second orientation the second side of the stop is facing upward.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1A is a perspective view of an electronic device with a casing and cap assembly in an attached closed position, according to certain aspects of the disclosure;

FIG. 1B is a perspective view of the electronic device with the casing and cap assembly in an attached open position, according to certain aspects of the disclosure;

FIG. 1C is a perspective view of the electronic device with the casing and cap assembly in a completely detached position, according to certain aspects of the disclosure;

FIG. 2A is a top view of a cap, according to certain aspects of the disclosure;

FIG. 2B is a front view of the cap, according to certain aspects of the disclosure;

FIG. 2C is a side view of the cap, according to certain aspects of the disclosure;

FIG. 3A is a first cross sectional view of a latching hole, according to certain aspects of the disclosure;

FIG. 3B is a second cross sectional view of the latching hole, according to certain aspects of the disclosure;

FIG. 3C is a third cross sectional view of the latching hole, according to certain aspects of the disclosure;

FIG. 4A is a perspective view of a first manipulation step of the cap, according to certain aspects of the disclosure;

FIG. 4B is a perspective view of a second manipulation step of the cap, according to certain aspects of the disclosure;

FIG. 4C is a perspective view of a third manipulation step of the cap, according to certain aspects of the disclosure;

FIG. 4D is a perspective view of a fourth manipulation step of the cap, according to certain aspects of the disclosure;

FIG. 4E is a perspective view of a fifth manipulation step of the cap, according to certain aspects of the disclosure;

FIG. 4F is a perspective view of a sixth manipulation step of the cap, according to certain aspects of the disclosure; and

FIG. 4G is a perspective view of a seventh manipulation step of the cap, according to certain aspects of the disclosure.

### DETAILED DESCRIPTION

In the drawings, like reference numerals designate identical or corresponding parts throughout the several views. Further, as used herein, the words “a”, “an”, and the like include a meaning of “one or more”, unless stated otherwise. The drawings are generally drawn not to scale unless specified otherwise or illustrating schematic structures or flowcharts.

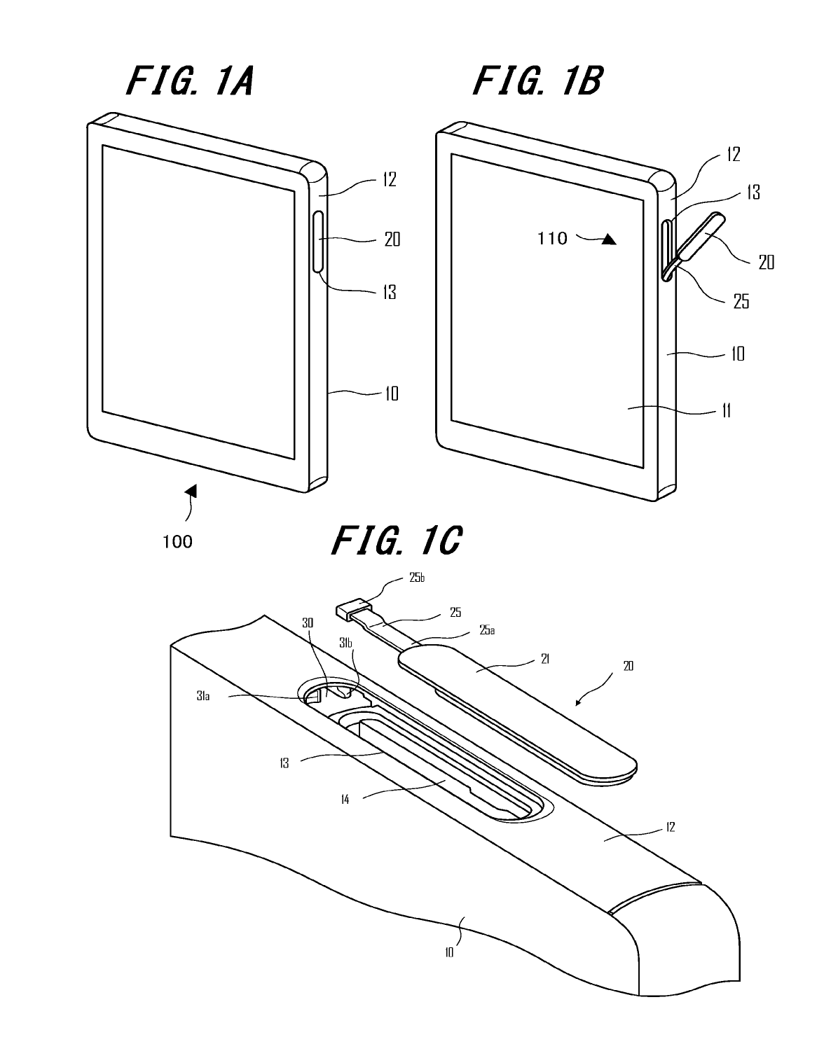

FIGS. 1A-1C are perspective views of an electronic device 100 with a casing and cap assembly 110 in an attached closed position, in an attached open position, and in a completely detached position, respectively and according to certain aspects of the disclosure.

The electronic device 100, e.g. a personal computer, a tablet, a phone, a media player, a camera, or the like, may include a casing 10 surrounding a screen 11 with an opening 13 that provides access to an electronic receptacle 14, e.g. a memory card slot, an USB input, an electric input, or the like.

The cap 20 may have a shape to follow the opening 13 and be made from flexible materials, e.g. synthetic resin alloys or rubber alloys, to provide a tight fit between the cap 20 and the opening 13.

The cap 20 may include a leg 25 with a stop 25b configured to be inserted inside a latching hole 30 of the opening 13, and a connection part 25a attached to a first end of the cap 20.

The latching hole 30 may lead onto the opening 13 and may longitudinally run below a side surface 12 of the electronic device 100. The latching hole 30 may include a pair of limitation members 31a, 31b placed between the opening 13 and the latching hole 30.

The cap 20 may be placed in the attached closed position to prevent external elements, e.g. water, dust, or dirt, from entering in the opening 13 and/or the electronic receptacle 14, as illustrated in FIG. 1A, in the attached open position to provide an access to the electronic receptacle 14 while maintaining the cap 20 affixed to the casing 10 of the electronic device 100, as illustrated in FIG. 1B, and in the completely detached position to remove the cap 20 from the casing 10 of the electronic device 100.

In the attached closed position, the leg 25 of the cap 20 may be completely inserted in the latching hole 30 of the casing 10 while the cap 20 may be lodged inside the opening 13 of the casing 10 to act as a seal for the opening 13 of the casing 10 and for the electronic receptacle 14 of the electronic device 100.

In the attached open position, the cap 20 may be dislodged from the opening 13 of the casing 10 and may remain moveably connected to the side surface 12 of the electronic device 100 via the leg 25 of the cap 20, wherein the leg 25 protrudes partially from the latching hole 30.

In the attached open position and in the attached closed position, the limitation members 31a, 31b of the latching hole 30 may limit the displacement of the stop 25b of the leg 25 to prevent the unintentional removal of the cap 20 from the latching hole 30 and the casing 10.

In the completely detached position, the cap 20 may be completely dislodged from the opening 13 of the casing 10 and the leg 25 of the cap 20 may be completely removed from the latching hole 30 and the casing 10. The complete removal of the cap 20 may be ensured by manipulating the leg 25 of the cap 20 to avoid the stop 25b from being blocked by the pair of limitations members 31a, 31b. The leg 25 may be manipulated such that the stop 25b can pass between the pair of limitation members 31a, 31b and not be blocked by the pair of limitation members 31a, 31b. For example, the stop 25b may be rotated to present a narrow part of the stop 25b that can fit and pass between the pair of limitation members 31a, 31b.

Similarly, the leg 25 may be reattached to the latching hole 30 of the casing 10 by manipulating the leg 25 of the cap 20 and sliding the stop 25b of the leg 25 through the pair of limitations members 31a, 31b and inside the latching hole 30.

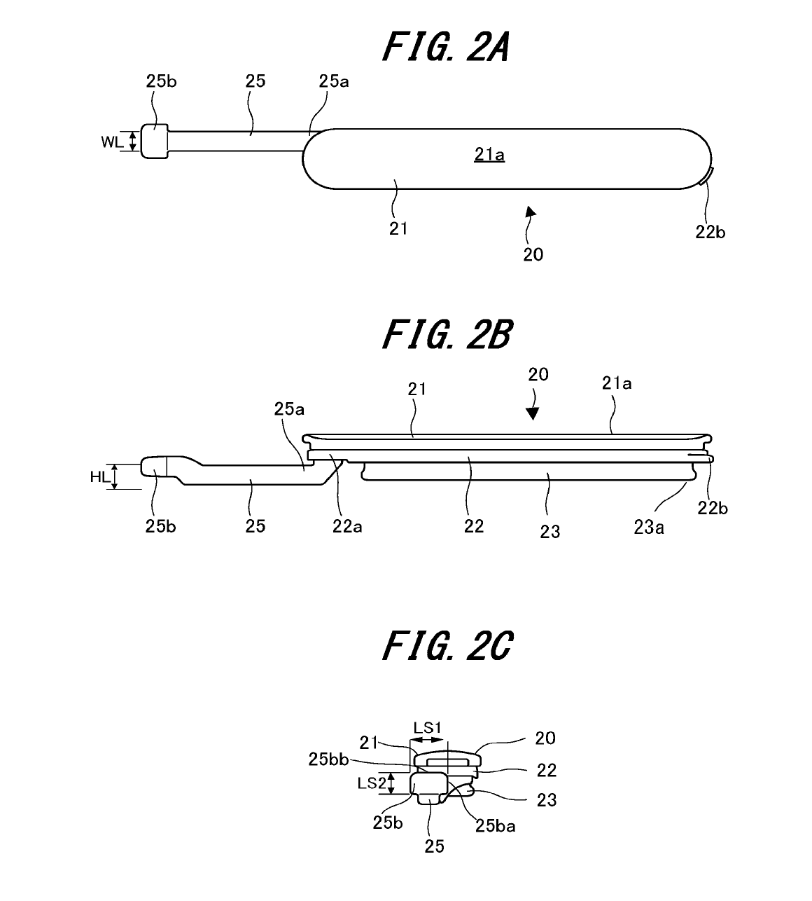

FIGS. 2A-2C are a top, a front, and a side views of the cap 20, respectively and according to certain aspects of the disclosure.

The cap 20 may include the leg 25, a first member 21, a second member 22, and a third member 23, wherein the first member 21 is stacked on the second member 22, and the second member 22 is stacked on the third member 23.

The leg 25 extends between the connection member 25a and the stop 25b along a longitudinal direction of the second member 22. In addition, the leg 25 may include a curved part near the connection member 25a and the stop 25b to facilitate the insertion of the leg 25 inside the latching hole 30. The leg 25 is characterized by a leg width WL and a leg height HL.

The stop 25b may include a wide lateral side 25ba configured to be blocked by the pair of limitation members 31a, 31b and a narrow lateral side 25bb configured to pass between the pair of limitation members 31a, 31b. For example, the wide lateral side 25ba may be characterized by a first side length LS1 that is wider than the leg width WL and the narrow lateral side 25bb may be characterized by a second side length LS2 that is the substantially the same as the leg height HL.

The first member 21 may include an external surface 21a configured to provide a flush surface with the side surface 12 of the electronic device 100, when the cap 20 is placed in the attached closed position.

The second member 22 may include a second member end part 22a to provide a connection to the leg 25 via the connection part 25a, and a tongue 22b that protrudes from the second member 22 to provide better fastening and sealing of the cap 20 to the opening 13.

The third member 23 may have a shape configured to act as a plug and/or a seal for the electronic receptacle 14, see FIG. 1C. For example, the third member 23 may have an oval shape lip 23a that matches the electronic receptacle 14.

The first member 21, the second member 22, the third member 23, and the leg 25 may be molded or machined in one or several pieces assembled and/or fastened together from one or several different flexible materials, such as resins, rubbers, elastomers or the like.

Alternatively, the leg 25 may be part of or affixed to the first member 21, the second member 22, the third member 23, or any combination thereof.

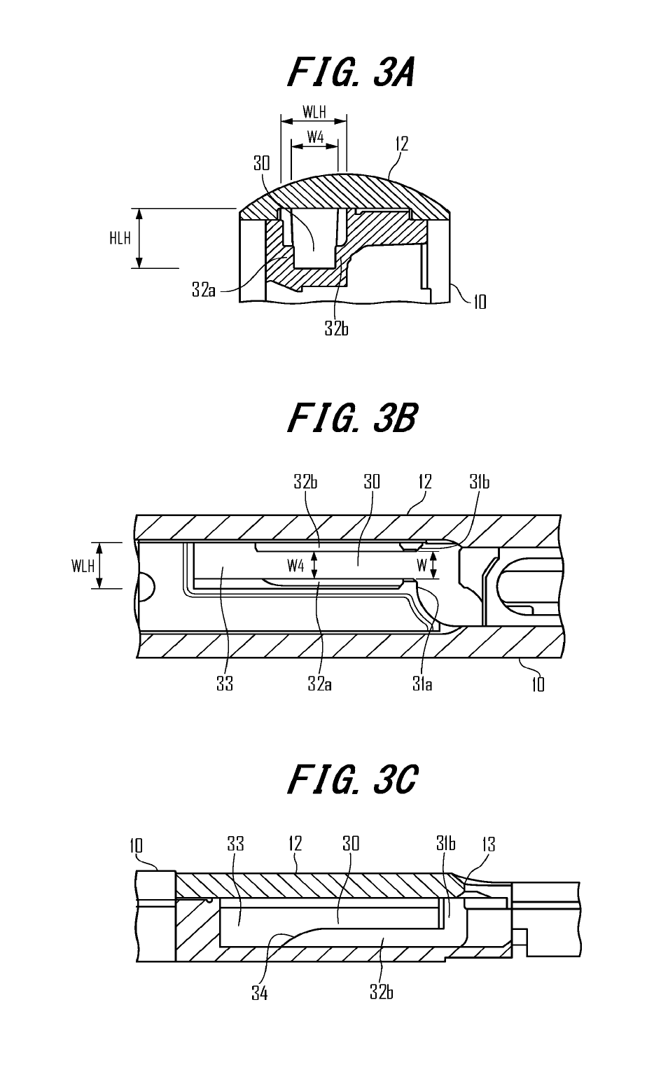

FIGS. 3A-3C are a first, a second, and a third cross sectional views of the latching hole 30, respectively and according to certain aspects of the disclosure.

The latching hole 30 may extend longitudinally below the side surface 12 from the opening 13 to receive completely the leg 25 of the cap 20. The latching hole 30 may include the pair of limitation members 31a, 31b located near the opening 13, a rail-less zone 33 located at an end of the latching hole 30, and a pair of rails 32a, 32b that extends from the pair of limitation members 31a, 31b up to the rail-less zone 33.

In addition, each rail of the pair of rails 32a, 32b may include a bevel 34 facing the rail-less zone 33.

The latching hole 30, the pair of limitation members 31a, 31b, and the pair of rails 32a, 32b may be configured for an insertion of the stop 25b and the leg 25, a sliding of the stop 25b, a blocking of the stop 25b, and complete withdrawal of the stop 25b and the leg 25.

The latching hole 30 may be characterized by a rectangular cross section having a latching hole width WLH and a latching hole height HLH that are sufficiently large to enable the insertion of the stop 25b. For example, the latching hole width WLH and the latching hole height HLH may be substantially the same or slightly larger, e.g. 15% larger, than the first side length LS1 of the wide lateral side 25ba.

Furthermore, the pair of rails 32a, 32b may protrude from internal opposite sides of the latching hole 30 to provide a sliding support for the wide lateral side 25ba of the stop 25b.

The pair of rails 32a, 32b may be spaced apart by a rail spacing W4 to guide the insertion of the narrow lateral side 25bb along the latching hole 30. For example, the rail spacing W4 may be smaller than the first side length LS1 but larger than the second side length LS2.

The bevels 34 of the pair of rails 32a, 32b may be configured to facilitate the transition of the stop 25b from the rail-less zone 33 to the pair of rails 32a, 32b.

The rail-less zone 33 may be configured to provide a volume in which the stop 25b can be rotated for at least 90 degrees.

The pair of limitation members 31a, 31b may be configured to facilitate the insertion of the stop 25b from the opening 13 to the latching hole 30, when the narrow lateral side 25bb is facing upward, and to block the exit of the stop 25b from the latching hole 30 to the opening 13, when the wide lateral side 25ba of the stop 25b is facing upward. The pair of limitation members 31a, 31b may be configured to permit the passage of the narrow lateral side 25bb of the stop 25b between the pair of limitation members 31a, 31b and configured to block the passage of the large lateral side 25ba of the stop 25b between the pair of limitation members 31a, 31b. For example, each limitation member of the pair of limitation members 31a, 31b may have a trapezoidal shape and provide a spacing W substantially equal to the rail width W4.

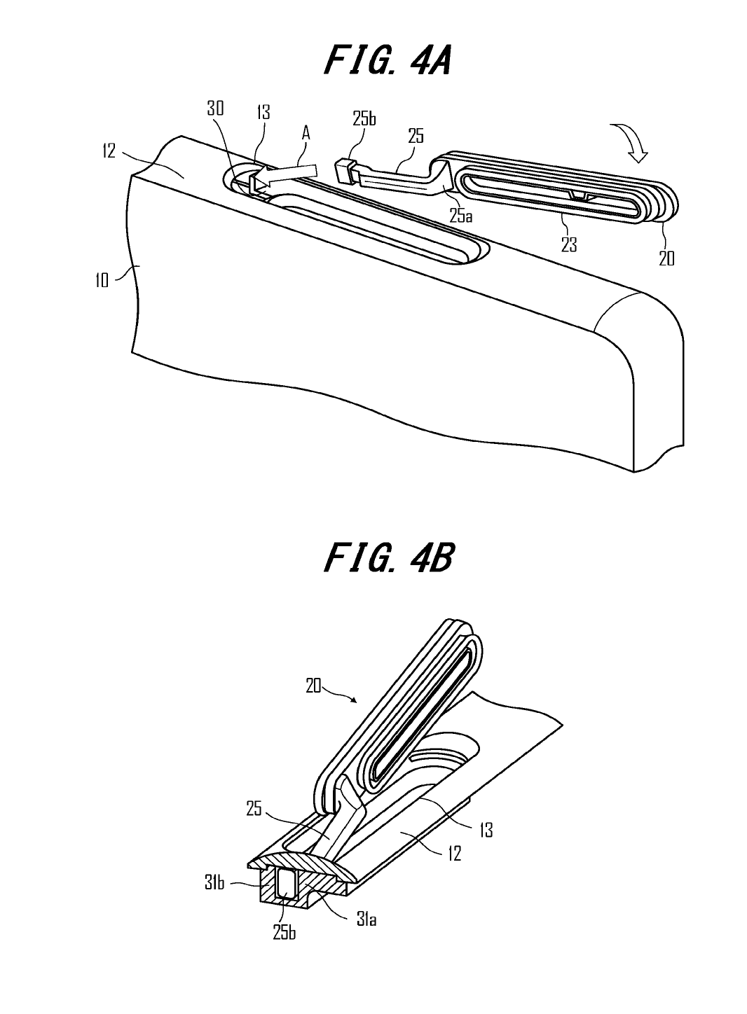

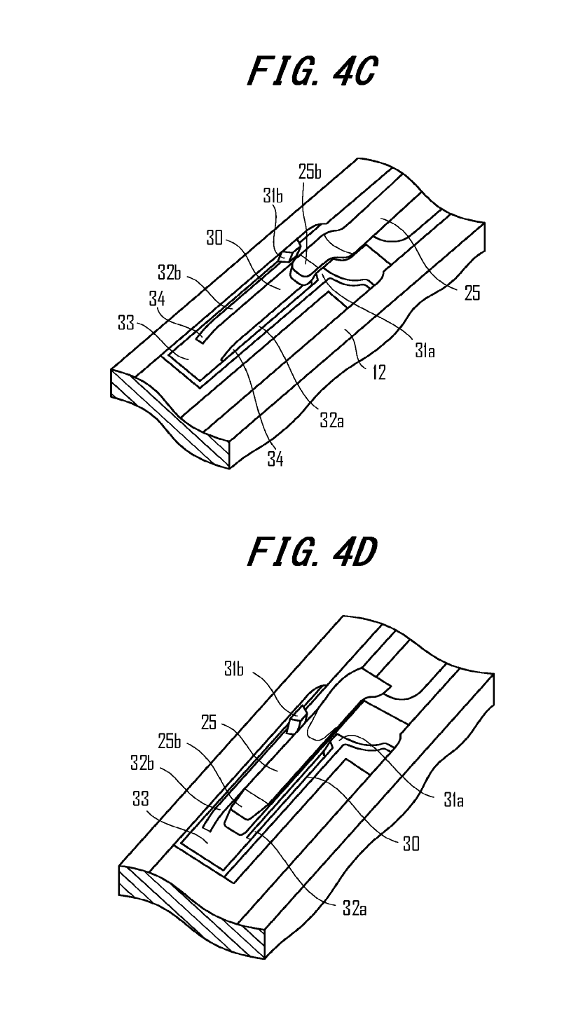

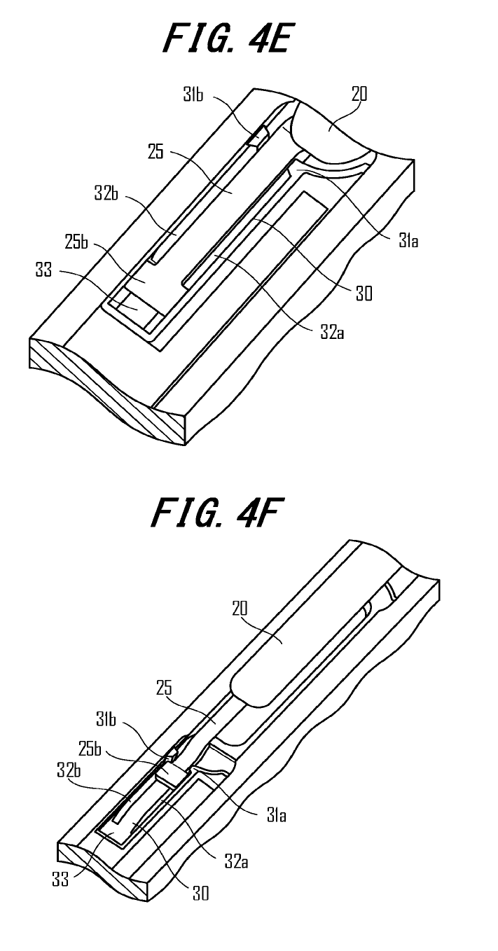

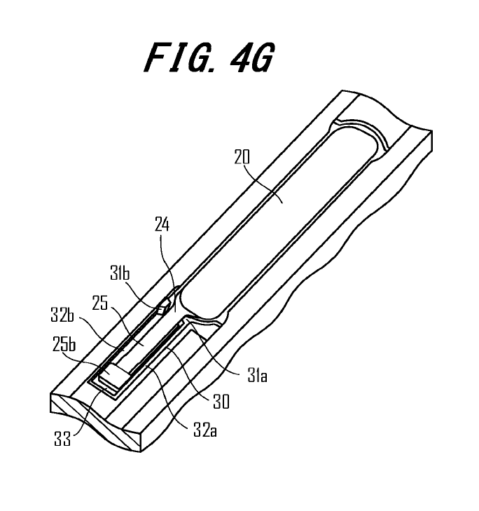

FIGS. 4A-4G are perspective views of a first manipulation step, a second manipulation step, a third manipulation step, a fourth manipulation step, a fifth manipulation step, a sixth manipulation step, and a seventh manipulation step of the cap 20, respectively and according to certain aspects of the disclosure.

The cap 20 may be configured to be manipulated from the completely detached position to the attached open position, from the attached open position to the attached closed position, and vice-versa.

The cap 20 may be manipulated from the completely detached position to the attached open position by rotating the cap 20 and the stop 25b from a first orientation to a second orientation, see FIG. 4A, inserting the stop 25b between the pair of limitation members 31a, 31b, see FIG. 4B, sliding the stop 25b between the pair of rails 32a, 32b until the stop 25b reaches the rail-less zone 33, see FIGS. 4C-4D, and pivoting back the cap 20 and the stop 25b from the second orientation to the first orientation, See FIG. 4E.

In the first orientation, the external surface 21b of the first member 21 is substantially parallel to the side surface 12 of the electronic device 100 and the large lateral side 25ba of the stop 25b is facing upwardly, see FIG. 4A, while in the second orientation the external surface 21b of the first member 21 is substantially perpendicular to the side surface 12 of the electronic device 100 and the narrow lateral side 25bb of the stop 25b is facing upwardly, see FIG. 4F.

When the cap 20 is in the attached open position, the stop 25b can slide back and forth on the pair of rails 32a, 32b from the rail-less zone 33 up to the pair of limitation members 31a, 31b wherein the pair of limitation members 31a, 31b prevent the stop 25b from further sliding outside the latching hole 30 and being detached from the electronic device 100, see FIGS. 4E-4F.

The cap 20 may be manipulated from the attached open position to the attached closed position by completely sliding the leg 25 inside the latching hole 30, e.g. the stop 25b is inside the rail-less zone 33, and inserting the cap 20 inside the opening 13, see FIG. 4G.

Similarly, the cap 20 may be manipulated from the attached open position to the completely detached position by rotating the stop 25b from the second orientation to the first orientation while the stop 25b is in the rail-less zone 33, and sliding the stop 25b between the pair of rails 32a, 32b, and between the limitations members 31a, 31b to extract the stop 25b from the latching hole 30 and the opening 13.

In one exemplary aspect, the cap 20 and the latching hole 30 may be configured to provide an angle difference between the first orientation and the second orientation that is equal to or less than 90 degrees. For example, the stop 25b of the cap 20 and the latching hole 30 may rely on geometrical shapes configured to provide an angle difference between the first orientation and the second orientation than less than 90 degrees. Particularly, the wide lateral side 25ba and the narrow lateral side 25bb may be oriented to form an obtuse angle.

The foregoing discussion discloses and describes merely exemplary embodiments of an object of the present disclosure. As will be understood by those skilled in the art, an object of the present disclosure may be embodied in other specific forms without departing from the spirit or essential characteristics thereof. Accordingly, the present disclosure is intended to be illustrative, but not limiting of the scope of an object of the present disclosure as well as the claims.

Numerous modifications and variations on the present disclosure are possible in light of the above teachings. It is therefore to be understood that within the scope of the appended claims, the disclosure may be practiced otherwise than as specifically described herein.

What is claimed is:

1. A casing and cap assembly, comprising:
a cap, the cap including:
a member,
a leg having a first end attached to the member, and
a stop attached to a second end of the leg, the stop including:
a first side, and
a second side directly adjacent to the first side and narrower than the first side; and
a casing to receive the cap, the casing including:
an opening to provide access to an electronic receptacle and to receive the member, and
a latching hole configured to guide the stop when the stop is in a first orientation and block the stop when the stop is in a second orientation.

2. The casing and cap assembly of claim 1, wherein the latching hole includes a pair of limitation members to provide a passage for the receipt of the stop in the latching hole when the stop is in the first orientation.

3. The casing and cap assembly of claim 2, wherein the latching hole further includes a rail-less zone located at an end of the latching hole and configured to provide a volume to rotate the stop from the first orientation to the second orientation and vice-versa.

4. The casing and cap assembly of claim 3, wherein the latching hole further includes a pair of rails extended between the pair of limitation members and the rail-less zone, and configured to provide the guidance of the stop when the stop is in the first orientation and the sliding of the stop when the stop is in the second orientation.

5. The casing and cap assembly of claim 4, wherein each rail of the pair of rails is ended by a bevel configured to facilitate a transition of the stop from the rail-less zone onto the pair of rails when the stop is in the second orientation.

6. The casing and cap assembly of claim 1, wherein the latching hole of the casing has a rectangular cross section having a latching hole width and a latching hole height larger than a first length of the first side of the stop.

7. The casing and cap assembly of claim 1, wherein the leg of the cap has leg width smaller than a first length of the first side of the stop and a leg height substantially equal to a second length of the second side of the stop.

8. The casing and cap assembly of claim 1, wherein the pair of rails is spaced apart by a rail spacing than is smaller than a first length of the first side of the stop and larger than a second length of the second side of the stop.

9. The casing and cap assembly of claim 8, wherein the pair of limitation members is spaced apart by the rail spacing.

10. The casing and cap assembly of claim 9, wherein each limitation member of the pair of limitation member has a trapezoidal shape.

11. A casing and cap assembly, comprising:
a cap, the cap including:
a first member to provide protection against external elements,
a second member stacked on the first member,
a third member stacked on the second member and configured to act as a seal for an electronic receptacle,
a leg having a first end attached to the second member, and
a stop attached to a second end of the leg, the stop including:
a first side, and
a second side directly adjacent to the first side and narrower than the first side; and
a casing to receive the cap, the casing including:
an opening to provide access to the electronic receptacle and to receive the first member, and
a latching hole configured to guide the stop when the stop is in a first orientation, and block the stop when the stop is in a second orientation.

12. The casing and cap assembly of claim 11, wherein the latching hole includes a pair of limitation members to provide a passage for the receipt of the stop in the latching hole when the stop is in the first orientation.

13. The casing and cap assembly of claim 12, wherein the latching hole further includes a rail-less zone located at an end of the latching hole and configured to provide a volume to rotate the stop from the first orientation to the second orientation and vice-versa.

14. The casing and cap assembly of claim 13, wherein the latching hole further includes a pair of rails extended between the pair of limitation members and the rail-less zone, and configured to provide the guidance of the stop when the stop is in the first orientation and the sliding of the stop when the stop is in the second orientation.

15. The casing and cap assembly of claim 14, wherein each rail of the pair of rails is ended by a bevel configured to facilitate a transition of the stop from the rail-less zone onto the pair of rails when the stop is in the second orientation.

16. The casing and cap assembly of claim 11, wherein the leg is attached to the third member via a connection member having a curved end configured to facilitate an insertion of the leg inside the latching hole.

17. The casing and cap assembly of claim 16, wherein the second member further includes a tongue configured to fasten the cap on the opening.

18. The casing and cap assembly of claim 16, wherein the third member includes an oval shaped lip configured to seal the electronic receptacle.

19. The casing and cap assembly of claim 11, wherein an angle difference between the first orientation and the second orientation is equal to or less than 90 degrees.

20. The casing and cap assembly of claim 19, wherein the first side of the stop and the second side of the stop have an adjacent angle that is equal to or less than 90 degrees.
